(19) United States
(12) Patent Application Publication
(10) Pub. No.: US 2014/0001500 A1
(43) Pub. Date: Jan. 2, 2014

(54) LED LIGHT BAR

(71) Applicant: ADVANCED OPTOELETRONIC TECHNOLOGY, INC., Hsinchu Hsien (TW)

(72) Inventor: MING-TA TSAI, Hsinchu (TW)

(73) Assignee: ADVANCED OPTOELECTRONIC TECHNOLOGY, INC., Hsinchu Hsien (TW)

(21) Appl. No.: 13/895,371

(22) Filed: May 16, 2013

(30) Foreign Application Priority Data
Jun. 29, 2012 (CN) 201210221160X

(51) Int. Cl. H01L 27/15

(52) U.S. Cl. CPC H01L 27/153
USPC 257/91

(57) ABSTRACT

An LED light bar includes a substrate, a plurality of LED chips, an encapsulation covering each of the LED chips, a protecting layer, a first cover and a second cover. The substrate includes a first surface and a second surface. A plurality of pairs of first electrode and second electrode are formed on the first surface. The LED chips are formed on the first surface of the substrate and electrically connected with the first electrodes and the second electrodes. The protecting layer covers the first electrodes and the second electrodes to protect them from moisture and dust. The first cover and the second cover covers on the first surface and the second surface of the substrate respectively.

### BACKGROUND

1. Technical Field

The disclosure generally relates to a light emitting diode (LED) light bar, and particularly to an LED light bar having protection to electrodes on a substrate thereof.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

An LED light bar generally includes a substrate and a plurality of light emitting diode chips arranged on the substrate. The substrate has conductive structures to electrically connect with the light emitting diode chips. An upper cover and a lower cover are formed on an upper side and a lower side of the substrate respectively. However, in the LED light bar described above, moisture is easy to enter into the space between the upper cover and the lower cover, and affect the properties of the conductive structures.

What is needed, therefore, is an LED light bar to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing an LED light bar in accordance with a first embodiment of the present disclosure.

FIG. 2 is a cross-sectional view showing an LED light bar in accordance with a second embodiment of the present disclosure.

### DETAILED DESCRIPTION

Embodiments of an LED light bar will now be described in detail below and with reference to the drawings.

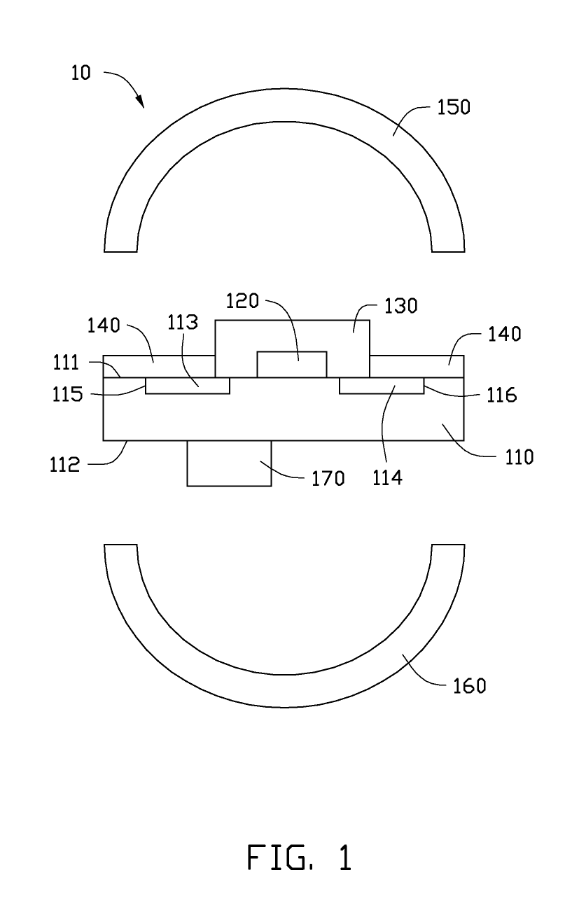

Referring to FIG. 1, an LED light bar 10 in accordance with a first embodiment is provided. The LED light bar 10 includes a substrate 110, a plurality of LED chips 120 arranged on the substrate 110, an encapsulation 130, a protecting layer 140, a first cover 150 and a second cover 160.

The substrate 110 has a first surface 111 and a second surface 112. A plurality of pairs of first electrode 113 and second electrode 114 are formed on the first surface 111 of the substrate 110. The first electrode 113 of each pair is electrically insulated from the second electrode 114 thereof. In this embodiment, the substrate 110 defines a first groove 115 and a second groove 116 on the first surface 111 thereof. The first groove 115 is configured to receive the first electrode 113. The second groove 116 is configured to receive the second electrode 114. Upper surfaces of the first electrode 113 and the second electrode 114 are coplanar with the first surface 111 of the substrate 110. The first electrode 113 and the second electrode 114 are made of a material selected from a group consisting of gold (Au), silver (Ag), nickel (Ni), copper (Cu) and alloys thereof.

The LED chips 120 are formed on the first surface 111 of the substrate 110. Each LED chip 120 is electrically connected with a corresponding pair of first electrode 113 and second electrode 114. A voltage is applied between the first electrode 113 and the second electrode 114 to make the LED chip 120 emits light. The LED chip 120 is made of a material selected from a group consisting of GaN, AlGaN, InGaN and AlInGaN.

The encapsulation 130 covers the LED chip 120 to prevent the LED chip 120 from being affected by moisture or dust in an outer environment. Preferably, the encapsulation 130 can be doped with phosphor particles. The phosphor particles absorb light emitted from the LED chip 120 and convert it into a light with different wavelength. The phosphor particles are made of a material selected from a group consisting of garnets, sulfides, silicates, nitrides and mixtures thereof.

The protecting layer 140 covers on the first electrodes 113 and the second electrodes 114. The protecting layer 140 positioned at two opposite ends of the encapsulation 130. The protecting layer 140 is configured to prevent moisture from attaching on the upper surfaces of the first electrodes 113 and the second electrodes 114 and causing a short-circuit failure between the first electrodes 113 and the second electrodes 114. The protecting layer 140 is made of transparent materials. In this embodiment, the protecting layer 140 is flat and made of a material selected from a group consisting of epoxy, silicone, polyphthalamide (PPA) and polymethyl methacrylate (PMMA).

The first cover 150 covers on the first surface 111 of the substrate 110. The second cover 160 covers on the second surface 112 of the substrate 110. Light from the LED chip 120 passes through encapsulation 130, and emits into the outer environment from the first cover 150. In this embodiment, the first cover 150 and the second cover 160 each have a curve-shaped (i.e., semicircular) configuration. The first cover 150 and the second cover 160 are attached on the first surface 111 and the second surface 112 of the substrate 110 respectively. The first cover 150 is made of transparent materials such as glass, polycarbonate (PC), polymethylmethacrylate (PMMA). The second cover 160 is made of metal. Heat generated by the LED chip 120 can be transferred to the second cover 160 through the substrate 110, and then transferred to the outer environment through the second cover 160.

Preferably, the LED light bar 10 further includes a driving device 170. The driving device 170 is formed on the second surface 112 of the substrate 110. The driving device 170 is configured to provide and distribute power for the LED chips 120. The second cover 160 covers on the driving device 170.

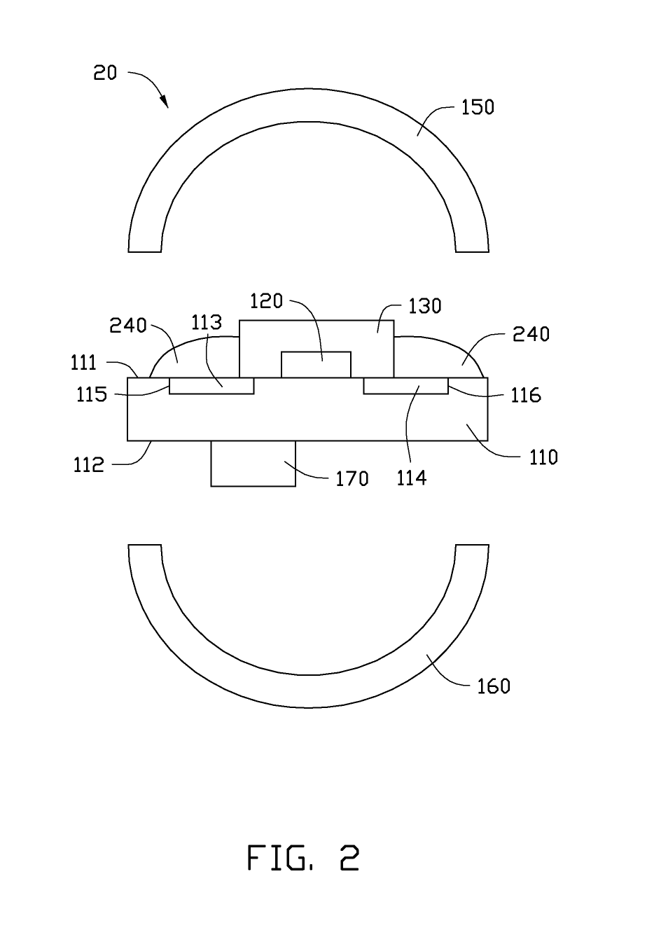

The shape of the protecting layer is not limited to the embodiment described above. Referring to FIG. 2, an LED light bar 20 in accordance with a second embodiment is provided. In this embodiment, an upper surface of the protecting layer 240 is a convex surface and a thickness of the protecting layer 240 is gradually decreased along a direction away from the encapsulation 130 toward lateral sides of the substrate 110. The protecting layer 240 is positioned at two opposite ends of the encapsulation 130. Because the protecting layer 240 has a convex surface, when light from the LED chip 120 transmits into the protecting layer 240 through the encapsulation 130, the convex surface can make the light emit laterally to increase the illumination angle of LED light bar 20.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED (light emitting diode) light bar, comprising:
a substrate, comprising a first surface and a second surface, a plurality of pairs of first electrode and second electrode being formed on the first surface;
a plurality of LED chips, formed on the first surface of the substrate, each LED chip being electrically connected with a corresponding pair of first electrode and second electrode;
an encapsulation, covering each of the LED chips;
a protecting layer, covering the plurality of pairs of first electrode and second electrode; and
a first cover and a second cover, covering on the first surface and the second surface of the substrate respectively.

2. The LED light bar of claim 1, wherein the protecting layer is made of transparent material.

3. The LED light bar of claim 1, wherein the protecting layer is made of a material selected from a group consisting of epoxy, silicone, polyphthalamide (PPA) and polymethyl methacrylate (PMMA).

4. The LED light bar of claim 1, wherein an upper surface of the protecting layer is flat.

5. The LED light bar of claim 1, wherein an upper surface of the protecting layer is convex.

6. The LED light bar of claim 5, wherein a thickness of the protecting layer is gradually decreased along a direction away from the encapsulation toward lateral sides of the substrate.

7. The LED light bar of claim 6, wherein the protecting layer is positioned at two opposite lateral sides of the encapsulation.

8. The LED light bar of claim 1, further comprising a driving device formed on the second surface of the substrate, the second cover covering the driving device.

9. The LED light bar of claim 1, wherein the substrate defines a first groove and a second groove in the first surface thereof, each of the first electrodes is formed in the first groove, and each of the second electrodes is formed in the second groove.

10. The LED light bar of claim 1, wherein upper surfaces of the first electrodes and the second electrodes are coplanar with the first surface of the substrate.

11. The LED light bar of claim 10, wherein, the first electrodes and the second electrodes each are made of a material selected from a group consisting of gold (Au), silver (Ag), nickel (Ni), copper (Cu) and alloys thereof.

12. The LED light bar of claim 1, wherein the first cover is made of a material selected from a group consisting of glass, polycarbonate (PC), polymethylmethacrylate (PMMA).

13. The LED light bar of claim 1, wherein the second cover is made of metallic material.
